(19) United States
(12) Patent Application Publication
(10) Pub. No.: US 2022/0318635 A1
(43) Pub. Date: Oct. 6, 2022

(54) ENERGY IDENTIFICATION METHOD FOR MICRO-ENERGY DEVICE BASED ON BP NEURAL NETWORK

(71) Applicant: United Microelectronics Center Co., Ltd, Chongqing (CN)

(72) Inventors: Chuting ZHANG, Chongqing (CN); Haopeng WANG, Chongqing (CN); Bin ZHANG, Chongqing (CN); Huaiwang ZENG, Chongqing (CN); Wenlong JIAO, Chongqing (CN); Miao WANG, Chongqing (CN)

(73) Assignee: United Microelectronics Center Co., Ltd, Chongqing (CN)

(21) Appl. No.: 17/053,069

(22) PCT Filed: Mar. 13, 2020
(86) PCT No.: PCT/CN2020/079102

§ 371 Date: Nov. 5, 2020

(30) Foreign Application Priority Data
Oct. 12, 2019 (CN) 201910967418.2

(51) Int. Cl. G06N 3/08; G01R 19/25

(52) U.S. Cl. CPC G06N 3/084; G01R 19/2503

(57) ABSTRACT

The present disclosure provides an energy identification method for a micro-energy device based on back propagation (BP) neural network, which includes the following steps: S1, sampling a dynamic voltage of a micro-energy device in an open-circuit state to obtain an original voltage signal, and denoising the original voltage signal by an adaptive threshold wavelet transform; S2, extracting an R wave peak value of the denoised voltage signal so as to obtain model input data; S3, establishing a BP neural network model, inputting data to train the model, and stopping training when a training error is smaller than a preset value, to obtain a qualified BP neural network model; and S4, identifying a to-be-identified voltage signal by using the BP neural network model obtained in the step S3. According to the present disclosure, accurate and rapid energy identification and classification can be carried out, and the classification result is reliable.

### CROSS REFERENCES TO RELATED APPLICATIONS

This is a Sect. 371 National Stage application of a PCT International Application No. PCT/CN2020/079102, filed on Mar. 13, 2020, which claims the benefits of priority to Chinese Patent Application No. 2019109674182, filed with CNIPA on Oct. 12, 2019, the contents of which are incorporated herein by reference in its entirety.

### TECHNICAL FIELD

The present disclosure relates to the field of smart micro-energy system, in particular, to an energy identification method for a micro-energy device based on BP neural network.

### BACKGROUND

At present, smart micro-energy systems with self-sensing, self-awakening, self-learning, and self-adapting gradually replace traditional energy management systems. The accurate identification of input energy is the key to smart micro-energy systems.

Since the voltage signal of the micro-energy device is interfered by the material itself and external factors such as the process technology, there may be a variety of noises with different strengths or different frequencies in the voltage signal. How to improve the adaptability of noise and the de-noising effect is one of the urgent problems to be solved in the energy recognition of micro-energy devices.

At present, the research directions of machine learning mainly include decision tree, random forest, artificial neural network, Bayesian learning, and so on. Compared with traditional machine learning algorithms such as the K-nearest neighbor algorithm and Bayesian classifier algorithm, back propagation (BP) neural network has obvious advantages in the following aspects:

1) BP neural network has stronger self-learning and self-adapting ability. BP neural network can automatically extract the output data during its training, and adaptively memorize the learned content in the network weights.

2) BP neural network has better generalization ability than traditional machine learning algorithms. Generalization ability usually refers to the ability of a machine or neural network to predict unknown data after a quantity of data training. Take the smart micro-energy system as an example. When a common machine learning algorithm, such as Naive Bayes classifier, is used to classify the output electrical forms of a variety of micro-energy devices, such algorithm can only classify the current training set samples (i.e., dynamic voltages of the micro-energy devices in an open-circuit state) and extract features, but the feature extraction effect for other data samples is poor. In contrast, the supervised BP neural network model divides the entire model training process into two processes: signal forward propagation and error back propagation. First, the training data enters the model for forward propagation. If there is an error between the result obtained by the output layer and the expected output result then in the second step, the error is back-propagated and the weight of the hidden layer is updated until the error is minimized. In this way, the weight of the model learned by iterative training reaches the optimal value. At this time, the model has good generalization ability, and is able to classify and identify other data samples more accurately.

3) BP neural network has good fault-tolerant ability, that is, when some neurons of BP neural network are damaged, the accuracy of feature classification and recognition of the whole model is not greatly affected.

4) BP neural network has good nonlinear mapping ability. The essence of BP neural network is to realize a mapping from input to output. The mathematical theory proves that when the number of hidden layer neurons in the three-layer BP neural network structure is sufficient, the neural network can approximate any nonlinear continuous function with any precision.

### SUMMARY

The present disclosure provides an energy identification method for a micro-energy device based on back propagation (BP) neural network. By using a supervised BP neural network model to identify and classify the output electrical forms of micro-energy devices, the accuracy of rapid energy recognition of composite micro-energy devices is improved. To solve the above technical problems, the present disclosure specifically adopts the following technical solutions:

an energy identification method for a micro-energy device based on BP neural network, including the following steps:

S1, sampling a dynamic voltage of an integrated micro-energy device in an open-circuit state to obtain an original voltage signal, and denoising the original voltage signal by an adaptive threshold wavelet transform;

S2, extracting an R wave peak value of the denoised voltage signal so as to obtain model input data;

S3, establishing a BP neural network model, inputting data to train the model, and stopping training when a training error is smaller than a preset value, to obtain a qualified BP neural network model;

S4, identifying a to-be-identified voltage signal by using the BP neural network model obtained in the step S3.

Preferably, the step S1 includes:

S101, continuously sampling a dynamic voltage of an integrated micro-energy device in an open-circuit state to obtain an original voltage signal;

S102, denoising the original voltage signal by an adaptive threshold wavelet transform algorithm; the formula is as follows:

$${φ}_{{2}^{- j} , k {2}^{- j}} ( t ) = {2}^{\frac{j}{2}} φ ( {2}^{j} t - k ) , {WT}_{x} ( j , k ) = {2}^{\frac{j}{2}} {\int }_{- ∞}^{+ ∞} x ( t ) {φ}^{*} ( {2}^{j} t - k ) dt$$

2^{-j} is a scale factor, k·2^{-j} is a shift factor, and φ*(t) is a conjugate of φ(t);

S103, performing a wavelet multi-level decomposition by using the number of wavelet decomposition levels and the wavelet basis function, and obtaining a wavelet decomposition coefficient w_{j,k} of a corresponding level, performing threshold processing on the wavelet decomposition coefficient w_{j,k}:

$${w}_{j , k} = \{ \begin{matrix}{w}_{j , k} & \vert {w}_{j , k} \vert \geq γ \\ 0 & \vert {w}_{j , k} \vert \leq γ\end{matrix}$$

γ is the threshold value and w_{j,k} is the wavelet decomposition coefficient.

Preferably, the step S2 includes: dividing the time window of each segment of the dynamic voltage, and searching a maximum value point in the window, so as to find the position of the to-be-collected R wave peak and obtain the total data set.

Preferably, the step S3 includes:

S301, initializing the structure of the BP neural network;

S302, normalizing the dynamic voltage, noise characteristics and sample sampling rate of the integrated micro-energy device in the open-circuit state as the input of the model, and the characteristic center of the integrated micro-energy device serves as the output of the model;

S303, setting an error function;

S304, dividing the total data set into a training set and a validation set, inputting the training set into the BP neural network model in two parts, and obtaining updated network weights and updated network thresholds after the first input;

S305, after the second input, stopping the training when the training error is 1%; determining the final network weights and the final network thresholds, and obtaining a qualified energy recognition model for micro-energy devices based on BP neural network;

S306, if the training error described in S305 cannot be reached, a new data sample is added to increase data samples for the first input training to update the network weights and the network thresholds, then performing step S305.

Preferably, initializing the structure of the BP neural network in step S301 includes: selecting a node number of an input layer, a node number of a hidden layer, and a node number of an output layer; randomly selecting a weight coefficient of the hidden layer and a weight coefficient of the output layer in the range of [−1, 1]; determining a learning rate and a smoothing factor, and selecting an activation function of the model.

Preferably, the training error includes a difference between the average value of the network weights updated by the first input and the average value of the final network weights, and a difference between the average value of the network thresholds updated by the second input and the average value of the final network thresholds.

Preferably, step S3 further includes: storing the qualified models in a model pool, and counting the qualified models. When the number of models reaches X, testing the obtained X qualified models using a test set and recording the accuracy of the models, so as to obtain the parameters corresponding to the best model.

Preferably, the integrated micro-energy device includes a micro fuel cell, a vibration energy collector, and a micro photovoltaic cell.

Compared with the traditional technology, the present disclosure has the following beneficial effects:

according to the method of the present disclosure, accurate and rapid energy identification and classification can be carried out, and the classification result is reliable, which has certain directive significance for the energy classification and identification of composite micro-energy devices. The method of the present disclosure has high anti-interference capability. A plurality of characteristics with high influence proportions in energy signal comparison of the micro-energy device are selected, including the dynamic voltage, noise characteristics and sample sampling rate of the micro-energy device in the open-circuit state. The BP neural network is used to identify and classify the energy of composite micro-energy devices. The BP neural network model has good fault-tolerant ability and non-linear mapping ability, so that the deviation of individual characteristic quantity will not greatly influence the overall classification results, so that the classification and recognition results have higher reliability and accuracy.

### BRIEF DESCRIPTION OF THE DRAWINGS

FIG. 1 is a schematic flowchart of the present disclosure.

FIG. 2 is a schematic flowchart of the BP neural network analysis process in the present disclosure.

### DETAILED DESCRIPTION OF THE PREFERRED EMBODIMENTS

The specific content of the present disclosure will be described in detail below with reference to the drawings and embodiments.

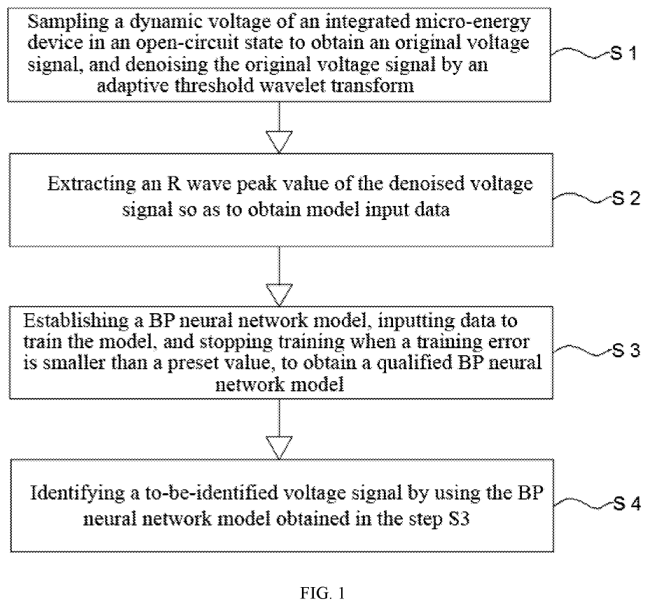

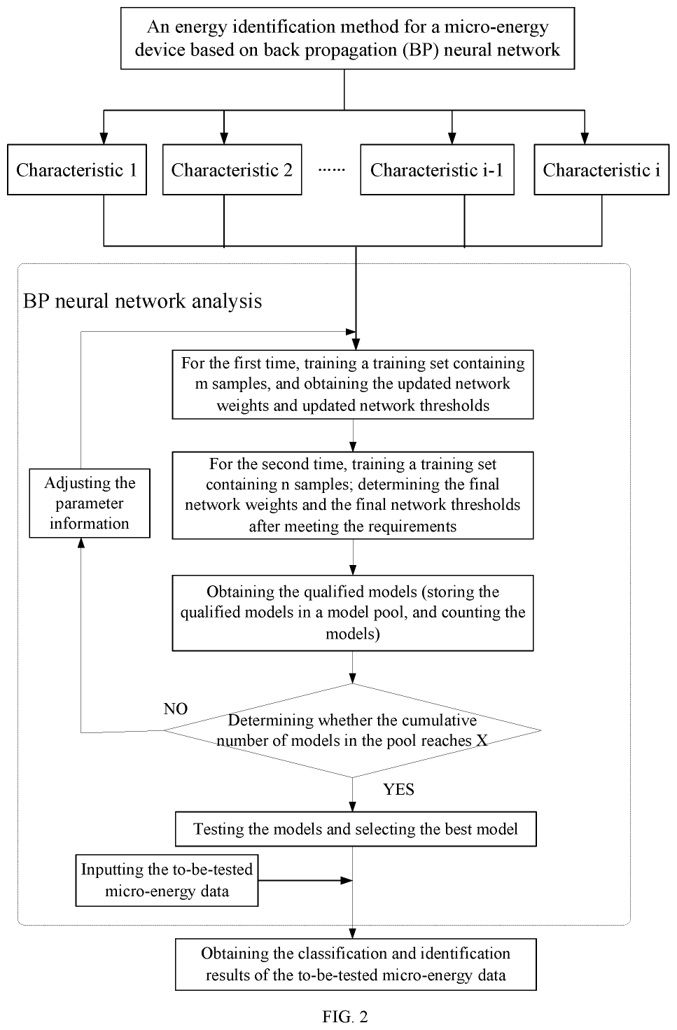

As shown in FIGS. 1 and 2, the present disclosure provides an energy identification method for a micro-energy device based on back propagation (BP) neural network. In this embodiment, the original voltage signal is obtained by continuously sampling the dynamic voltage of three types of micro-energy devices (micro fuel cell, vibration energy collector, and micro photovoltaic cell) in the open-circuit state. The sampled voltage signal containing noise and complex redundant information is subjected to wavelet transforming to remove the noise interference of the original data, thereby completing the preprocessing of the voltage data signal.

Since the voltage signal of the micro-energy device is interfered by the material itself and external factors, there may be a variety of noises with different strengths or different frequencies in the voltage signal. To improve the noise adaptability and denoising effect, an adaptive threshold wavelet transform algorithm is used to denoise the original voltage signal.

The formula of the adaptive threshold wavelet transform algorithm is as follows:

Discrete wavelet function:

$${φ}_{{2}^{- j} , k {2}^{- j}} ( t ) = {2}^{\frac{j}{2}} φ ( {2}^{j} t - k )$$

Discrete wavelet transform:

$${WT}_{x} ( j , k ) = {2}^{\frac{j}{2}} {\int }_{- ∞}^{+ ∞} x ( t ) {φ}^{*} ( {2}^{j} t - k ) dt$$

2^{-j} is the scale factor, k·2^{-j} is the shift factor, and φ*(t) is the conjugate of φ(t). Selecting a proper wavelet decomposition level number and a proper wavelet basis function, performing a wavelet multi-level decomposition to obtain a wavelet decomposition coefficient w_{j,k} of a corresponding level. Performing threshold processing on the wavelet decomposition coefficient w_{j,k}:

$${w}_{j , k} = \{ \begin{matrix}{w}_{j , k} & \vert {w}_{j , k} \vert \geq γ \\ 0 & \vert {w}_{j , k} \vert \leq γ\end{matrix}$$

γ is the threshold value and w_{j,k} is the wavelet decomposition coefficient.

The wavelet threshold denoising process can reduce the low-scale and high-frequency interference signals in the original voltage signal data to a certain extent. Then, by extracting the R wave peak value of the denoised voltage signal, the discrete voltage data are obtained. Since the energy of the voltage signal is mostly concentrated on the R wave peak, the R wave peak is regarded as the energy peak of the voltage. By dividing the time window of each segment of the dynamic voltage and searching a maximum value point in the window, the position of the to-be-collected R wave peak can be found.

Let the sample number in the total data set be K, randomly select M samples from the total data set to form a training set as the input of the BP neural network. The number of R wave peak values contained in each sample is N, and M*N wave peak values are contained in M samples. The sampling rate of the training samples calculated according to time T is about

$$\frac{M N}{T} ,$$

and the sample number in the test set is K−M.

A BP neural network model is established. The model of the present disclosure adopts a three-layer network structure including an input layer, a hidden layer, and an output layer. In the entire training process, first, training set sample data are input into the BP neural network for training, so as to obtain a neural network prediction model. The main steps to establish the BP neural network model are:

S301, initializing the structure of the BP neural network; the node number of the input layer is i, the node number of the hidden layer is j, and the node number of the output is n; randomly selecting a weight coefficient v[i][j] of the hidden layer and a weight coefficient w[j][n] of the output layer in the range of [−1,1]; determining the learning rate a and smoothing factor b, and selecting the sigmoid function as the activation function of the model.

S302, normalizing the dynamic voltage, noise characteristics and sample sampling rate of each micro-energy device in the open-circuit state as the input of the model; the output of the model is the characteristic center of each of the three micro-energy devices.

S303, assigning a random number within the interval [−1, 1] to each connection weight, and the error function is set as:

$$e = {( {\sum }_{i = 0}^{l} ( {d}_{oi} - y {o}_{oi} ) )}^{2} / 2$$

dₒᵢ is the expected output vector of the corresponding data, yoₒᵢ is the output vector of the output layer of the corresponding data.

The specific training steps are shown in FIG. 2. In the present disclosure, the training set is divided into two inputs. m training samples are input at the first time, n training samples are input at the second time, m+n=M. M is the total number of training samples. (m=n=M/2 is selected for the first time, and will be adjusted according to actual data)

S304, for the first time, inputting a training set containing m samples into the BP neural network classification prediction model, and obtaining the updated network weights and updated network thresholds.

S305, for the second time, inputting a training set containing n samples into the BP neural network classification prediction model, stopping the training when the training error is 1%; determining the final network weights and the final network thresholds, and obtaining a suitable energy recognition model for micro-energy devices.

The training error includes the difference between the average value of the network weights updated by the first input and the average value of the final network weights, and the difference between the average value of the network thresholds updated by the second input and the average value of the final network thresholds.

S306, if the training error cannot be reached during the training, adding a new data sample to increase data samples for the first input training to update the network weights and the network thresholds, then performing step S305.

To obtain the best model, the identification method of the present disclosure may also include storing the qualified models in a model pool, and counting the qualified models. When the number of models reaches X, a test set is used to test the obtained X qualified models and record the accuracy of the models, so as to obtain the parameters corresponding to the best model.

When using the BP neural network classification prediction model described in the present disclosure to identify the micro-energy, the results of classification and identification can be obtained simply by inputting the to-be-tested micro-energy data into the model.

Finally, it should be noted that the above embodiments are only used to illustrate the technical schemes of the present disclosure without limitation. Although the present disclosure has been described in detail with reference to the preferred embodiments, those skilled in the art should understand that modifications or equivalent substitutions can be made on the technical schemes of the present disclosure without departing from the spirit and scope of the technical schemes of the present disclosure, and should be covered by the scope of the claims of the present disclosure.

1. An energy identification method for a micro-energy device based on back propagation (BP) neural network, comprising:
S1, sampling a dynamic voltage of an integrated micro-energy device in an open-circuit state to obtain an original voltage signal, and denoising the original voltage signal by an adaptive threshold wavelet transform;
S2, extracting an R wave peak value of the denoised voltage signal, so as to obtain model input data;
S3, establishing a BP neural network model, inputting data to train the model, and stopping training when a training error is smaller than a preset value, to obtain a qualified BP neural network model;
S4, identifying a to-be-identified voltage signal by using the BP neural network model obtained in step S3.

2. The energy identification method for a micro-energy device based on BP neural network according to claim 1, wherein step S1 comprises:
S101, continuously sampling a dynamic voltage of the integrated micro-energy device in the open-circuit state to obtain the original voltage signal;
S102, de-noising the original voltage signal by an adaptive threshold wavelet transform algorithm; the formula is as follows:
$${φ}_{{2}^{- j} , k {2}^{- j}} ( t ) = {2}^{\frac{j}{2}} φ ( {2}^{j} t - k ) , {WT}_{x} ( j , k ) = {2}^{\frac{j}{2}} {\int }_{- ∞}^{+ ∞} x ( t ) {φ}^{*} ( {2}^{j} t - k ) dt ,$$
wherein 2^{-j} is a scale factor, k·2^{-j} is a shift factor, and φ*(t) is a conjugate of φ(t);
S103, performing a wavelet multi-level decomposition by using a wavelet decomposition level number and a wavelet basis function, obtaining a wavelet decomposition coefficient w_{j,k} of a corresponding level, and performing threshold processing on the wavelet decomposition coefficient w_{j,k}:
$${w}_{j , k} = \{ \begin{matrix}{w}_{j , k} & \vert {w}_{j , k} \vert \geq γ \\ 0 & \vert {w}_{j , k} \vert \leq γ\end{matrix}$$
wherein γ is a threshold value, and w_{j,k} is a wavelet decomposition coefficient.

3. The energy identification method for a micro-energy device based on BP neural network according to claim 2, wherein step S2 comprises: dividing a time window of each segment of the dynamic voltage, and searching a maximum value point in the window, to find a position of a to-be-collected R wave peak and obtain a total data set.

4. The energy identification method for a micro-energy device based on BP neural network according to claim 3, wherein step S3 comprises:
S301, initializing a structure of the BP neural network;
S302, normalizing the dynamic voltage, noise characteristics and sample sampling rate of the integrated micro-energy device in the open-circuit state as an input of the model, and a characteristic center of each integrated micro-energy device serves as an output of the model;
S303, setting an error function;
S304, dividing the total data set into a training set and a validation set, inputting the training set into the BP neural network model in two parts, and obtaining updated network weights and updated network thresholds after a first input;
S305, after a second input, stopping the training when the training error is 1%; determining the final network weights and the final network thresholds, and obtaining a qualified energy recognition model for micro-energy devices based on BP neural network;
S306, if the training error in step S305 cannot be reached, a new data sample is added to increase data samples for the first input training to update the network weights and the network thresholds, then performing step S305.

5. The energy identification method for a micro-energy device based on BP neural network according to claim 4, wherein initializing the structure of the BP neural network in step S301 comprises: selecting a node number of an input layer, a node number of a hidden layer, and a node number of an output layer; randomly selecting a weight coefficient of the hidden layer and a weight coefficient of the output layer in a range of [−1, 1]; determining a learning rate and a smoothing factor, and selecting an activation function of the model.

6. The energy identification method for a micro-energy device based on BP neural network according to claim 4, wherein the training error includes a difference between an average value of the network weights updated by the first input and an average value of the final network weights, and a difference between an average value of the network thresholds updated by the second input and an average value of the final network thresholds.

7. The energy identification method for a micro-energy device based on BP neural network according to claim 4, wherein step S3 further comprises: storing the qualified models in a model pool, and counting the qualified models; when the number of models reaches X, testing the obtained X qualified models using a test set and recording accuracy of the models, so as to obtain parameters corresponding to the best model.

8. The energy identification method for a micro-energy device based on BP neural network according to claim 1, wherein the integrated micro-energy device comprises a micro fuel cell, a vibration energy collector, and a micro photovoltaic cell.

9. The energy identification method for a micro-energy device based on BP neural network according to claim 2, wherein the integrated micro-energy device comprises a micro fuel cell, a vibration energy collector, and a micro photovoltaic cell.

10. The energy identification method for a micro-energy device based on BP neural network according to claim 3, wherein the integrated micro-energy device comprises a micro fuel cell, a vibration energy collector, and a micro photovoltaic cell.

11. The energy identification method for a micro-energy device based on BP neural network according to claim 4, wherein the integrated micro-energy device comprises a micro fuel cell, a vibration energy collector, and a micro photovoltaic cell.
